(19) United States
(12) Patent Application Publication
(10) Pub. No.: US 2014/0102876 A1
(43) Pub. Date: Apr. 17, 2014

(54) METHOD AND DEVICE TO MODIFY PROPERTIES OF MOLECULES OR MATERIALS

(71) Applicant: UNIVERSITE DE STRASBOURG (Etablissement Public National a Caractere Scientifique, Culturel et P.., Strasbourg (FR)

(72) Inventors: James A. Hutchison, Strasbourg (FR); Tal Schwartz, Strasbourg (FR); Cyriaque Genet, Strasbourg (FR); Eloise Devaux, Strasbourg (FR); Thomas W. Ebbesen, Strasbourg (FR); Paolo Samori, Strasbourg (FR)

(73) Assignee: UNIVERSITE DE STRASBOURG (Etablissement Public National a Caractere Scientifique, Culturel et P.., Strasbourg (FR)

(21) Appl. No.: 14/115,140

(22) PCT Filed: May 7, 2012
(86) PCT No.: PCT/IB2012/002206

§ 371 Date: Dec. 24, 2013

Related U.S. Application Data
(60) Provisional application No. 61/483,177, filed on May 6, 2011.

(51) Int. Cl. B01J 19/12

(52) U.S. Cl. CPC B01J 19/12
USPC 204/157.15; 422/186.01; 422/68.1

(57) ABSTRACT

A method and a device to modify the properties of molecules or materials. A method to modify the chemical properties, the work function, the electrochemical potential and/or the NMR frequency of one or more molecules, biomolecules or materials, method includes the steps of:

providing a reflective or photonic structure (1) which has an electromagnetic mode which is resonant with a transition in the molecules, biomolecules or material (2); and placing the molecule(s), biomolecule(s) or material (2) in or on a structure of the previous type.

### FIELD OF THE INVENTION

The present invention is related to the field of matter state or type transformation or modification by photon exchange, in particular concerning molecules or materials, more particularly organic molecules or materials, and involving a transition in said molecules or materials.

The present invention concerns more particularly a method and a device able to modify, preferably in a controlled manner, certain physical-chemical features or properties of molecules or materials, biomolecules or materials.

### BACKGROUND OF THE INVENTION

It is commonly known that an electromagnetic field can interact with a quantum system by the exchange of photons. When this interaction is strong enough to overcome decoherence effects, new hybrid light-matter states can form.

Indeed, through rapid exchange of photons (with photon exchange rate faster than any dissipation process), matter can enter into the so-called “strong coupling” regime with the surrounding electromagnetic field which leads to the formation of two new eigenstates separated by the Rabi splitting energy, as shown in FIGS. 1a and 1b.

Strong coupling has been extensively studied with atoms, semiconductors and quantum wells as it offers much potential in physics, especially in areas such as Bose-Einstein type condensation of polaritons, lasing and quantum information processing (see in particular bibliographic references No. 1 to 18 mentioned at the end of the present specification).

Nevertheless, the implication of these considerations in the fields of molecular science and material science have not been considered, nor a fortiori studied, up to now, despite the fact that strong coupling with organic molecules lead to exceptionally large vacuum Rabi-splittings (hundreds of meV) due to their large transition dipole moments (see bibliographic references No. 19 to 27 mentioned at the end of the present specification).

On the other hand, there has been, and still exists, a strong and constant request from the concerned scientific community, but also from the industrial actors in chemistry, biochemistry and materials, to influence, control and investigate chemical reactions and more generally the chemical and physico-chemical properties of molecules, biomolecules and materials by simply modifying the local environment or conditions, without adding any supplementary component, substance or medium, without specifically interfering by means of an agent or device and without modifying usual state or reaction parameters such as pressure, temperature, concentration or similar.

Now, the inventors have found, in an unexpected and surprising manner, that one can indeed influence a chemical reaction by strongly coupling the energy landscape governing the reaction pathway to vacuum fields and, in particular, that the work function and reactivity can be changed by strongly coupling a given molecular material with the vacuum electromagnetic field.

### SUMMARY OF THE INVENTION

Thus, the main object of the present invention concerns a method to modify the chemical properties, the work function, the electrochemical potential and/or the NMR frequency of one or more molecules, biomolecules or material, said method being characterised in that it mainly comprises the steps of:

providing a reflective or photonic structure which has an electromagnetic mode which is resonant with a transition in said molecules, biomolecules or material;

placing said molecule(s), biomolecule(s) or material in or on a structure of the previous type.

Typically, the inventive method is applied to a functional device comprising said reflective or photonic structure.

Preferably, the working circumstances and conditions of the method are set in such a way that the Q-factor (the ratio of the wavelength of the resonance divided by the half-width of the resonance) of the electromagnetic mode is at least 10, most preferably at least 30 or higher.

According to two alternative embodiments of the invention, related to two different physical realisations, the electromagnetic mode can be either a surface plasmon mode or a cavity mode.

It seems appropriate, in view of the findings made by the inventors and explained later or, that the molecules or material together with the cavity or plasmon structure be thought of as a single entity with new energy levels and therefore with its own distinct properties.

Depending on the nature of the practical implementation of the inventive method, the concerned transition in the molecules, biomolecules or material is an electronic transition, a vibrational transition or a nuclear spin transition.

Typically, the reflective structure can be made of a single metal film or of two opposed metal films.

In accordance with a possible specific use of the inventive method, said latter may consist, by means of coupling to local electromagnetic vacuum field and exploiting the resulting rearrangement of the energy levels of the molecules, biomolecules or material, in controlling a chemical reaction by influencing at least one of the following criteria or parameters of said reaction: reactivity of the molecules, biomolecules or material intented to react; kinetics of the reaction; rate and/or yield of the reaction; thermodynamics of the reaction.

Alternatively or in addition, the method may consist in tuning or dynamically controlling the value of the work function of the molecules, biomolecules or material.

Thus, the invention proposes a new approach to tuning the work function by resonant interaction with its electromagnetic environment, i.e. by strongly coupling a molecular material with the vacuum electromagnetic field which leads to the formation of hybrid light-matter states with very different energies.

As explained and shown in connection with the more detailed description later on, the change in work function occurs with both plasmonic and Fabry-Perot resonant structures and it occurs even in the dark since the coupling is with the vacuum field.

Indeed, even in the absence of light, a residual splitting always exists due to coupling to vacuum (electromagnetic) fields in the cavity.

Furthermore, the inventors have noticed that the inventive method has the additional property of being angle dependent relative to the surface, which can lead to unique functionalities.

Thus, said method may also consist in providing a dispersive photonic resonance mode and in using the angle dependency of the work function to control, to monitor or to influence a transition in said molecules, biomolecules or material and/or to selectively exploit or to model the results of said transition, in particular its expression in the environment.

The present invention also encompasses a device able to modify the chemical properties, the work function, the electrochemical potential and/or the NMR frequency of one or more molecules, biomolecules or materials, said device being characterized in that said device comprises a reflective or photonic structure which has an electromagnetic mode which is resonant with a transition in said molecules, biomolecules or material(s), said structure being confined or open.

Said device may be one of an electronic device, an optical device, a photovoltaic device or a light emitting device, in particular an organic or molecular light emitting device.

The inventive device further shows the features exposed before in relation to the Q-factor and possibly concerned transition.

According to the invention, the reflective or photonic structure may comprise plasmonic structures, the electromagnetic mode being a surface plasmon mode, or consist of an optical microcavity, preferably a Fabry-Perot cavity, the electromagnetic mode being a cavity mode, said structure being preferably made of a metal film or of two opposed metal films.

Depending on the concerned application, the reflective structure may comprise two metallic electrodes or two dielectric mirrors in a sandwich structure, the distance between said electrodes or mirrors being adjusted to resonate with an electronic transition in the molecules, biomolecules or material arranged within said structure.

In relation to a specific implementation of the inventive device, said latter may be a sample holder or part of a sample holder of a NMR spectroscopy or imaging machine, the reflective structure of said device having an electromagnetic mode which is resonant with the nuclear spin transition(s) to be analyzed or detected.

Furthermore, the invention comprises also a machine or apparatus able and intended to perform at least one electronic, optic, magnetic or chemical function, wherein said machine or apparatus comprises at least one device as described before, said device being designed to perform the method mentioned previously.

### BRIEF DESCRIPTION OF THE DRAWINGS

The file of this patent contains at least one drawing executed in color. Copies of this patent with color drawings will be provided by the Patent and Trademark Office upon request and payment of the necessary fee.

The invention will be further described hereinafter by way of non limitative examples and in connection with the attached schematical drawings wherein:

FIGS. 1a and 1b illustrate a simplified energy landscape showing the interaction of a HOMO-LUMO (S₀-S₁) transition of a molecule resonant with a cavity mode [symbol] ω_{c}. When energy exchange between the molecular transition and the cavity is rapid compared to energy loss, strong coupling leads to the formation of two hybrid light-matter (polaritonic) states |P+ [symbol] and |P− [symbol] , separated by the Rabi splitting energy [symbol] Ω_{R} (note that the absolute energy of the ground level of the coupled system |0 [symbol] may also be modified by strong coupling).

FIGS. 2a to 2f illustrate:

2a: The molecular structure of spiropyran (SPI) and merocyanine (MC).

2b: A schematic diagram of the energy landscape connecting the two isomers in the ground and first excited state where k_{Ex} and k_{Ex}′ are the rates of photoexcitation and the others, the rates of the internal pathways, e.g. k₁ represents the sum of non-radiative and radiative relaxation rates from MC* to MC. Vibrational sub-levels are not included for clarity.

2c: The ground state absorption spectra of SPI (black) and MC (red) in PMMA film.

2d: The structure of the cavity (note that cavity and non-coupled measurements were done concurrently on the same film).

2e: Schematic diagram of the energy landscape connecting the two isomers in the ground and first excited state, with modification of the MC states by strong coupling and the appearance of the polariton states |P+) [symbol] and |P− [symbol] separated by the Rabi splitting [symbol] Ω_{R}.

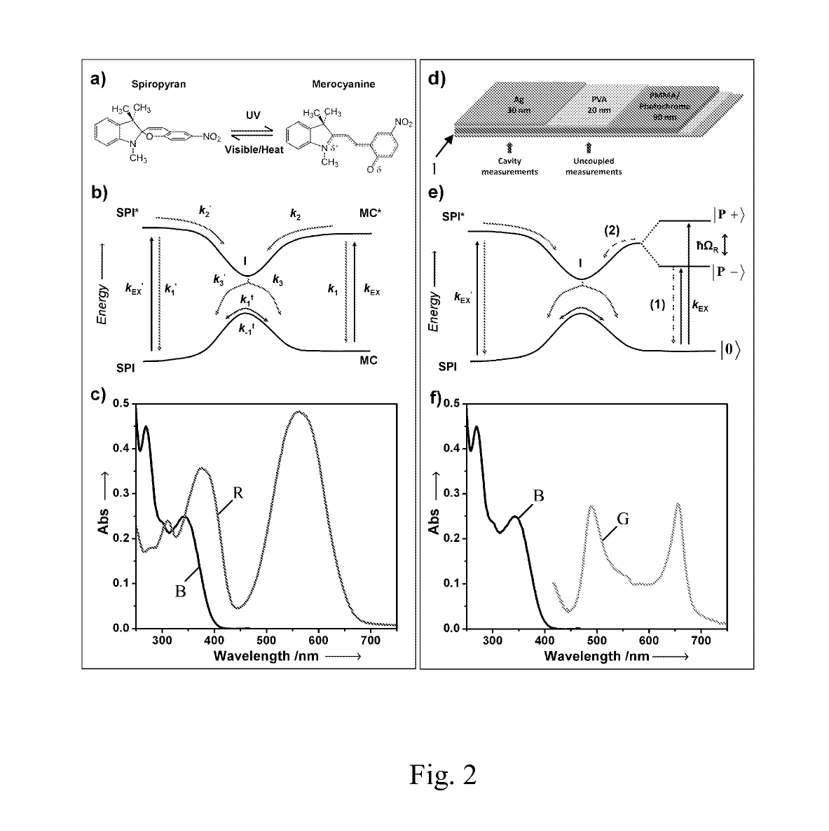

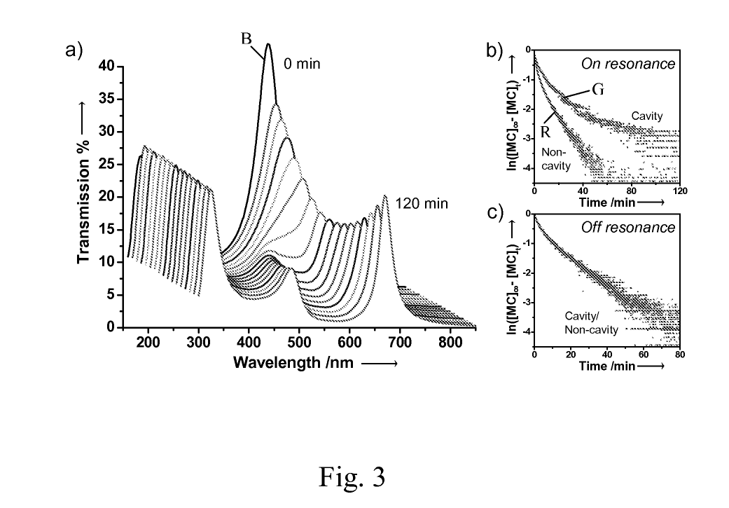

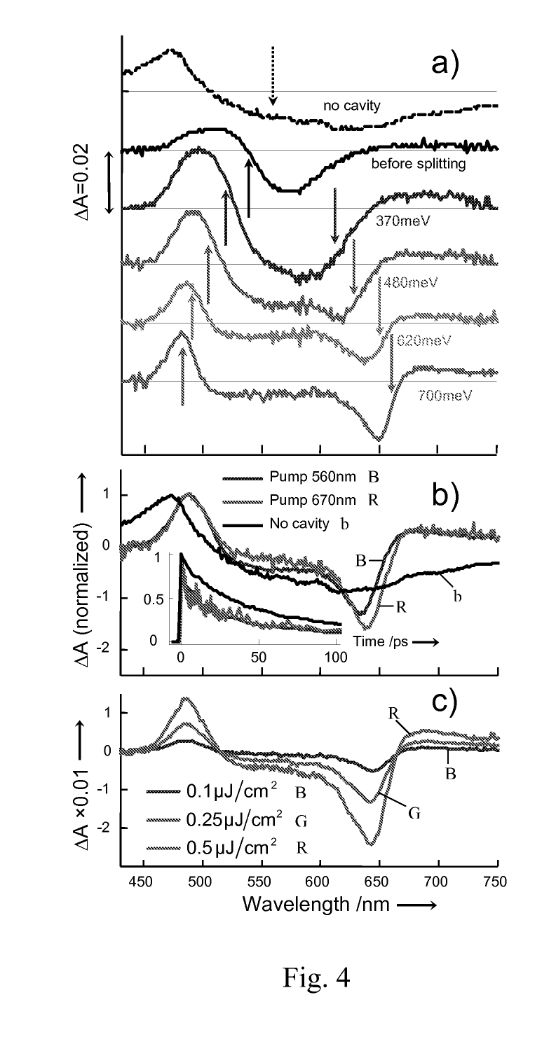

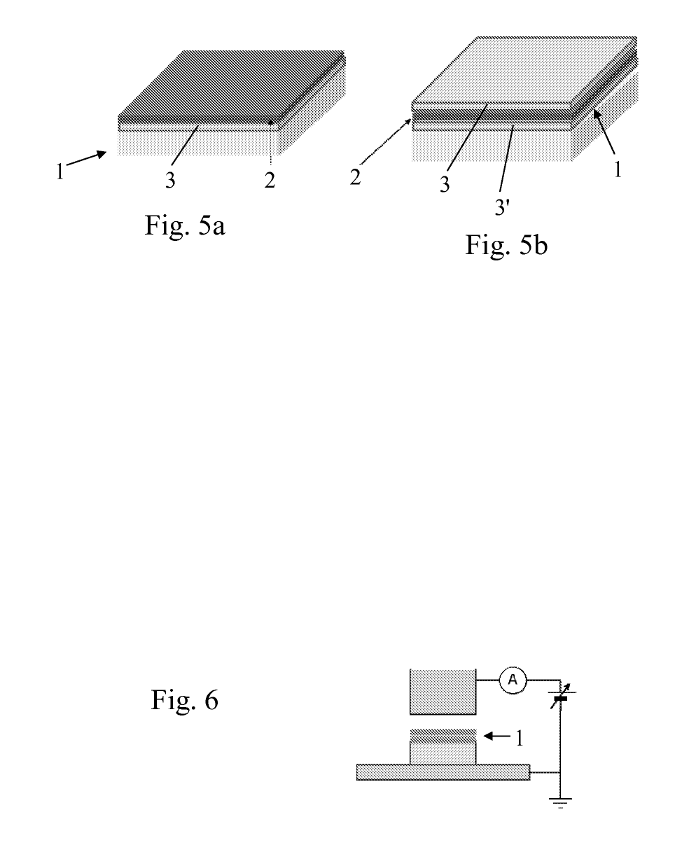

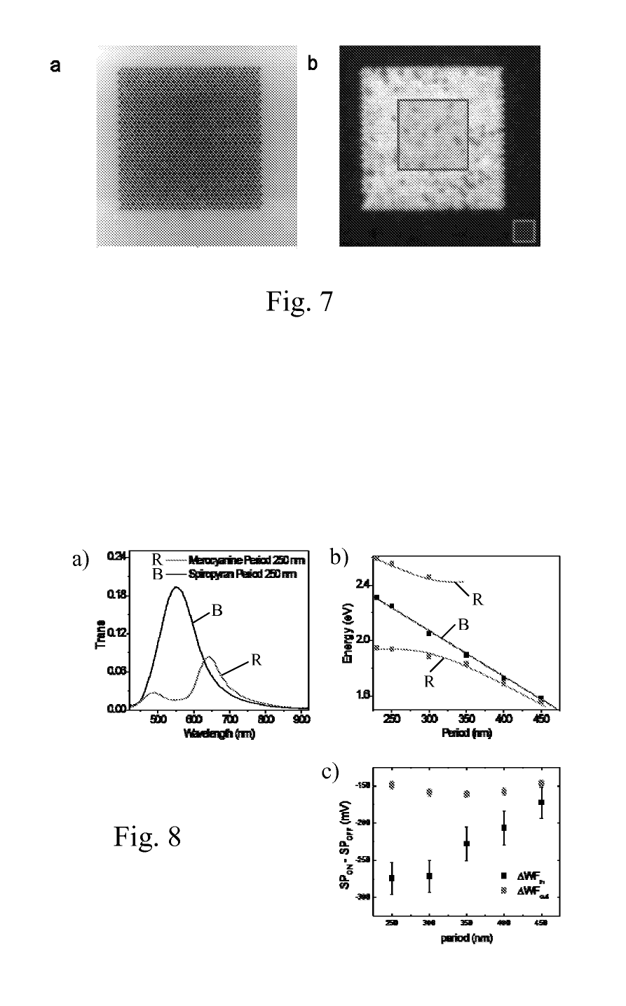

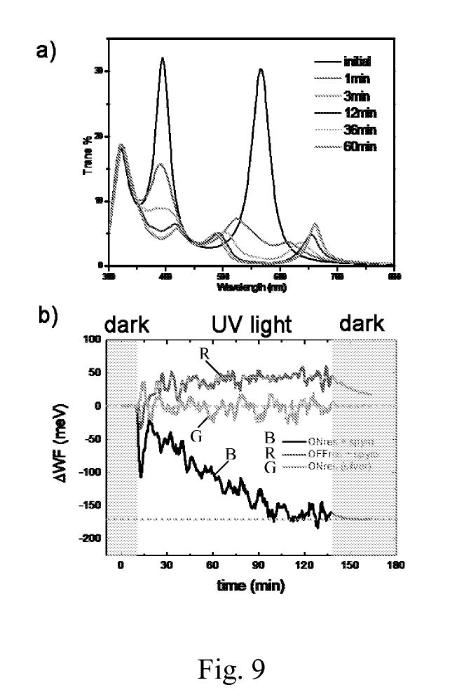

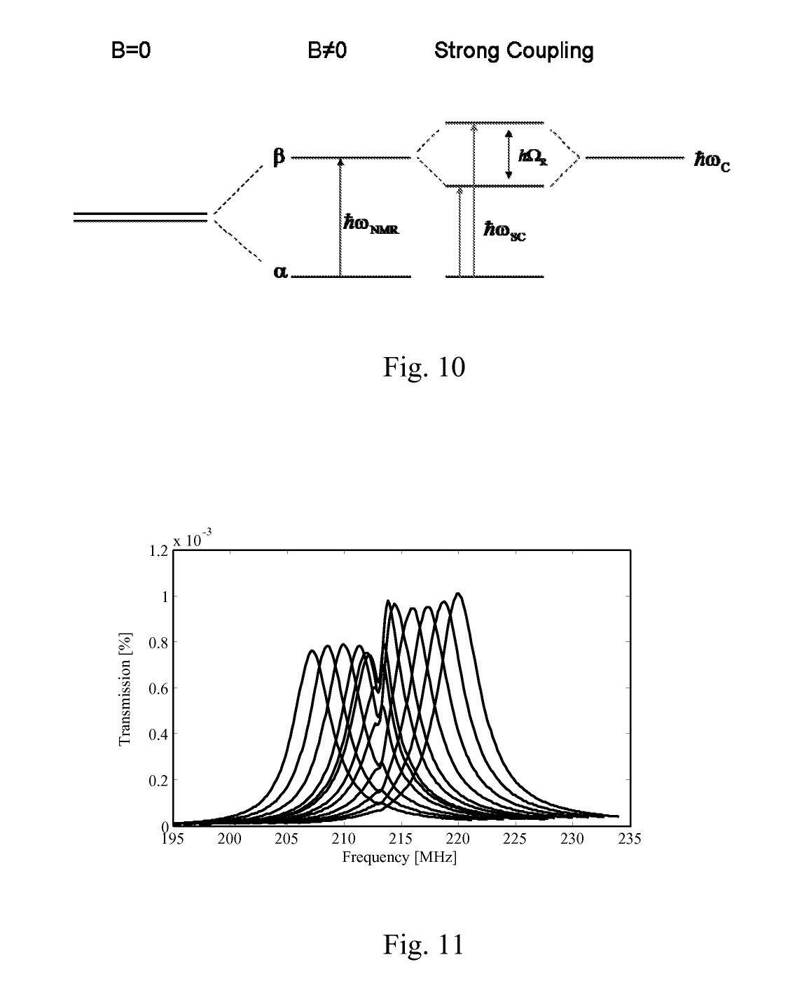

2f: The ground state absorption spectra of SPI (black) in PMMA and of the coupled system (green, structure shown in FIG. 2d) determined experimentally in the available wavelength window by measuring the transmission T and reflection R of the sample (Abs=1−T−R).

FIGS. 3a to 3c illustrate:

3a: Transmission spectrum of the coupled system in the cavity as a function of irradiation time at 330 nm where the Ag film has a transparency window as seen in the spectra (notice that the initial Fabry-Perot mode at ca. 560 nm (black curve) splits into two new modes as the SPI to MC photoreaction proceeds).

3b: Kinetics of the growth of the MC absorbance (i.e. concentration) measured for the bare molecules (red) and the coupled system (green) in the configuration shown in FIG. 2d, in other words, the uncoupled molecules were irradiated through one mirror on the same sample as the cavity system involving two mirrors. The negative log plot stems from taking ln([MC]_{∞}−[MC]ₜ) versus t. For this case, in which the cavity resonance is tuned to exactly match the MC absorption at 560 nm, the difference in the rates increases with the degree of strong coupling.

3c: In contrast, when the cavity thickness is tuned such that at no angle is there resonance between cavity modes and the MC absorption at 560 nm, there is no difference in photoisomerization rate in or out of the cavity.

FIGS. 4a to 4c illustrate the transient spectra and kinetics of the coupled system:

4a: Transient spectra recorded immediately after the 150 fs pump pulse at 560 nm for a bare molecular film and the cavity system for different coupling strengths. The arrows mark the position of the bare molecule absorption peak (topmost curve), and the linear transmission peaks of the cavity for each coupling strength. Note that the apparent bleaching at the absorption wavelengths of the lower polariton just reflects the fact that its absorption cross-section to higher excited states is lower than that of the ground state to |P− [symbol] while the reverse is true at the wavelengths where upper polariton absorbs (eq. 3).

4b: Transient spectra at the maximum coupling strength recorded after excitation at different wavelengths as indicated, insert: decay kinetics at the same wavelengths compared to the absence of cavity.

4c: Transient spectrum as a function of excitation intensity.

FIGS. 5a and 5b illustrate two different embodiments of a resonant structure according to the invention, more particularly as a metallic hole array (FIG. 5a) and as a Fabry-Perot cavity (FIG. 5b).

FIG. 6 illustrates schematically the analytical KPFM setup used to extract the work function of the studied samples placed on or in the resonant structure of FIG. 5a or 5b.

FIGS. 7a (Z range=100 nm) and 7b (Z range=200 meV) illustrate respectively an AFM image and a KPFM image of an Ag film with a hole array and a PMMA film containing SPI coated on its surface.

FIG. 8a illustrates the variation of the absorption transition ratios depending on the wavelength for the sample of FIGS. 7a and 7b.

FIG. 8b illustrates the variation of the work function for the two isomers with the value of the period.

FIG. 8c illustrates the variation of ΔWFin and ΔWFout depending on the value of the period.

FIG. 9a illustrates the variation of the absorption transition rate depending on the wavelength.

FIG. 9b illustrates the variation of ΔWF (or ΔΦ_{obs}) depending on the time in the dark and under UV irradiation.

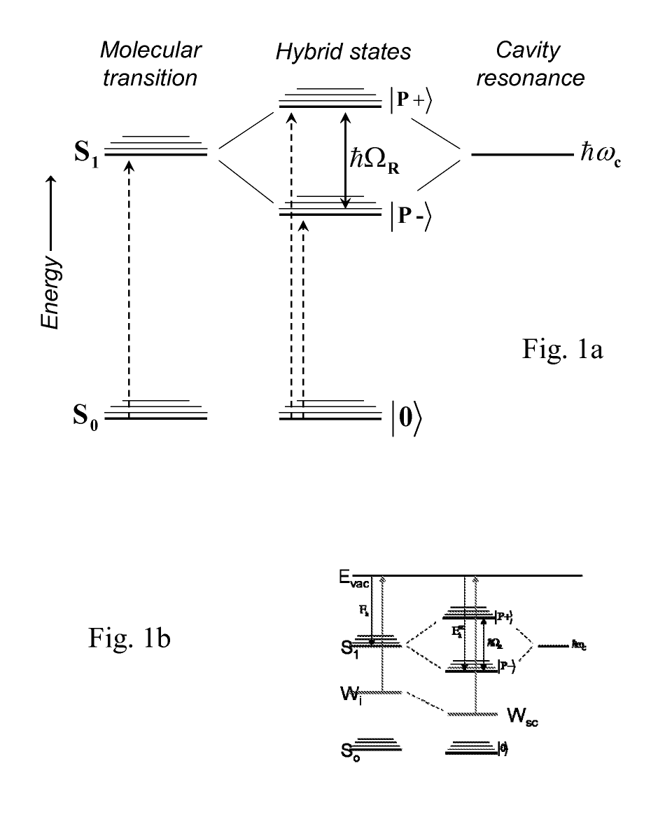

FIG. 10 is a schematical representation similar to FIGS. 1a and 1b, illustrating the consequence on the resonant NMR frequency of strong coupling.

FIG. 11 illustrates the transmission rate depending on the frequency of a Cobalt sample in a tunable resonant cavity.

### DETAILED DESCRIPTION OF THE INVENTION

As indicated herein before, the invention concerns a method to modify the chemical properties, the work function, the electrochemical potential and/or the NMR frequency of one or more molecules, biomolecules or material.

Said method is characterised in that it mainly comprises the steps of:

providing a reflective or photonic structure 1 which has an electromagnetic mode which is resonant with a transition in said molecules, biomolecules or material 2;

placing said molecule(s), biomolecule(s) or material 2 in or on a structure of the previous type.

The invention also concerns a device able to modify the chemical properties, the work function, the electrochemical potential and/or the NMR frequency of one or more molecules, biomolecules or material.

Said device is characterized in that it comprises a reflective or photonic structure 1 which has an electromagnetic mode which is resonant with a transition in said molecules, biomolecules or material 2, said structure 1 being confined or open.

Several illustrative examples showing the working of the inventive principles in connection to different non limitative implementations will now be described in the following specification.

First, one must remember that, in the absence of dissipation, the Rabi splitting energy [symbol] Ω_{R} (FIG. 1) between the two new hybrid light-matter states is given, for a two level system at resonance with a cavity mode, by the product of the electric field amplitude E of the cavity and the transition dipole moment d (see reference 13):

$${Ω}_{R} = 2 E \cdot d \cdot \sqrt{{n}_{ph} + 1} = 2 \sqrt{\frac{ ω}{2 {ɛ}_{0} v}} \cdot d \cdot \sqrt{{n}_{ph} + 1} \qquad ( 1 )$$

where [symbol] ω is the cavity resonance or transition energy, ∈₀ the vacuum permittivity, ν the mode volume and nph the number of photons in the cavity. As can be seen, even when nₚₕ goes to zero, there remains a finite value for the Rabi splitting, [symbol] Ω_{RV}, due to the interaction with the vacuum field. This splitting is itself proportional to the square root of the number of molecules in the cavity \sqrt{nₘₒₗ} (see references 13 and 14) which in turn implies that the [symbol] Ω_{RV} is proportional to the square root of the concentration

$$( \sqrt{\frac{{n}_{mol}}{v}} ) ,$$

as observed experimentally for instance in the case of molecules strongly coupled with surface plasmons (see reference 25).

To illustrate practically an example of the modification of the chemical landscapes by strong coupling to vacuum fields, the inventors chose as a model system a photochrome which provides one form with a transition dipole moment d to favour strong coupling (Eq. (1)) and the associated chemical reaction is monomolecular to avoid any complications due to diffusion. The photochromic molecule is the spiropyran (SPI) derivative 1′,3′-dihydro-1′,3′,3′-trimethyl-6-nitrospiro[2H-1-benzopyran-2,2′-(2H)-indole] which undergoes ring breaking following photoexcitation to form a merocyanine (MC) (FIG. 2a). The extended conjugation of the latter results in strong absorption in the visible (FIG. 2c, red curve). The reverse reaction can be achieved photochemically or by thermal means. The simplified potential energy surface for this photochrome is shown schematically in FIG. 2b. The absorption spectrum of the SPI form in a poly(methylmethacrylate) (PMMA) film is shown in FIG. 2c. Upon irradiation at 330 nm, the SPI photoisomerizes to the MC form and the absorbance of the MC form (λₘₐₓ=560 nm, red curve FIG. 2c) increases until the photostationary state is reached.

To form the resonant cavity structure 1, the PMMA film containing the photochrome 2 was sandwiched between two Ag mirrors 3 and 3′, insulated from direct contact to the Ag by thin poly(vinyl alcohol) (PVA) films as shown in FIG. 2d. The first Ag mirror was deposited on the glass substrate but note that the second mirror was not sputtered nor evaporated directly on the PMMA film to avoid any possible perturbation of the chemical system. Instead the top Ag film was deposited on a separate block of poly(dimethylsiloxane) (PDMS) which was then transferred to the sample, effectively encapsulating the photochrome in the microcavity.

More precisely, the samples were prepared as follows: The bottom Ag layer was sputtered onto a quartz slide. Then the PVA was spin cast (1% by weight aqueous solution at 3000 rpm) followed by the PMMA containing the SPI (1% by weight PMMA and 1% by weight SPI in toluene at 2200 rpm) before adding the second PVA layer. The top Ag film was evaporated onto PDMS and pressed against the PVA layer to form the cavity. If this structure was heated for 10 minutes at 35° C., the PDMS could be peeled away leaving the Ag layer attached to the PVA. Irradiation to the stationary state was done at 10⁻³ mbar pressure to avoid photo-oxidation of the photochrome. Irradiation power density was ˜1 mW/cm² and it was verified that the rate of isomerization scaled linearly with excitation intensity, ruling out any effects due to heat accumulation inside the cavity structure. The spectra were recorded on either a Shimadzu UV-3101 spectrophotometer or under a Nikon TE-200 microscope connected to an Acton SpectraPro 300i spectrograph and CCD camera (Roper Scientific). The transient spectroscopy was carried out using 150 fs pulses from a Ti:sapphire amplifier (Spitfire Pro, Spectra-Physics) pumping an optical parametric amplifier (TOPAS, Light Conversion) to give tunable excitation wavelengths for a pump-probe setup (Helios, Ultrafast Systems).

The transmission spectrum of this cavity structure is characterised by two features—a peak at 326 nm due to the transparency window of silver corresponding to its plasma frequency, and the fundamental Fabry-Perot cavity mode, which for a total PVA/PMMA/PVA thickness of 130 nm occurs at ˜560 nm (these cavity transmission features can be seen in FIG. 3a, black curve). The Fabry-Perot mode is therefore resonant with the absorption of MC. UV irradiation of the cavity at 330 nm causes formation of MC just as for the case of the isolated PMMA film.

When the MC is strongly coupled to the vacuum field in the cavity, the resulting formation of the hybrid states (or polaritons) is evidenced by the splitting of the absorption into two new peaks (green curve FIG. 2f). In brief, at the photostationary state, ca. 80% of the MC species are strongly coupled and the vacuum Rabi splitting is in the order of 700 meV (FIG. 2f-see also reference 41). In other words, the new hybrid states, |P+ [symbol] and |P− [symbol] , have absorptions at ±350 meV relative to the transition energy of the uncoupled MC (2.2 eV). Note that this Rabi splitting does not arise from the photons used to probe the system but is only due to vacuum field as can be seen from the fact that the spectrum of the coupled molecules is independent of the weak light intensity used to record it.

The photoisomerization kinetics inside and outside the cavity is now analysed. The detailed photoisomerization mechanism, schematically simplified in FIG. 2b, is still in debate in the literature due to its complexity and is reported to involve several intermediate isomers, including the triplet manifold, here collectively shown as a single species I (see references 28 to 32). Nevertheless, the reaction proceeds with observed first order kinetics in solution. An overall first order reaction mechanism (k_{obs}) is also predicted from the simplified reaction diagram in FIG. 2b where k_{obs} is a complex function of the quantum yields of the various individual photoinduced steps:

$$\frac{d [ MC ]}{d t} = - {k}_{obs} [ MC ] + b \\ with \\ {k}_{obs} = ( \frac{{k}_{3}^{′}}{{k}_{3} + {k}_{3}^{′}} \frac{{k}_{2}}{{k}_{1} + {k}_{2}} + \frac{{k}_{3}}{{k}_{3} + {k}_{3}^{′}} \frac{{k}_{2}^{′}}{{k}_{1}^{′} + {k}_{2}^{′}} ) {k}_{ex} \\ and \\ b = \frac{{k}_{3}}{{k}_{3} + {k}_{3}^{′}} \frac{{k}_{2}^{′}}{{k}_{1}^{′} + {k}_{2}^{′}} {{k}_{ex} [ SPI ]}_{0} \qquad ( 2 )$$

This rate equation assumes that the intermediates SPI*, I and MC* are in a stationary state and it is simplified by irradiation at the isosbestic point for the two species at ˜330 nm. The photo-stationary (PS) concentration ratio under the experimental conditions for this model is given by:

$$\frac{{[ MC ]}_{PS}}{{[ SPI ]}_{PS}} = \frac{{k}_{3} {k}_{2}^{′}}{{k}_{3}^{′} ( {k}_{1}^{′} + {k}_{2}^{′} )} ( 1 + \frac{{k}_{1}}{{k}_{2}} ) \qquad ( 3 )$$

In a polymer matrix, the internal isomerization processes are further complicated by convolution with the heterogeneous segmental motion of the polymer resulting in deviations from exponential behaviour (see reference 32). The kinetic build up of MC in the PMMA matrix (but outside the cavity) during UV irradiation at 330 nm shows indeed deviation from linearity when plotted on a log scale (red points in FIG. 3b). Also shown in FIG. 3a is the progression of the same reaction via the transmission spectra of the cavity structure. The Fabry-Perot mode is reduced and splits as the MC concentration increases. Using transfer matrix simulations, the transmission spectra as a function of time allow us to calculate the absorbance of MC at each time. This data is superimposed on that of the bare molecular film in FIG. 3b, making a slight correction for the different intensities of 330 nm light impinging on the polymer layer for the open structure and for the cavity (around 20% higher in the latter case). It is clear (FIG. 3b) that the while the rates measured for the two systems are similar at early times, as the reaction proceeds, the observed photo-isomerization rate slows down significantly in the cavity structure. This retardation corresponds to the onset of strong-coupling conditions and the formation of the hybrid light-matter states. The larger the splitting, the slower is the overall reaction reaching a fraction of the initial rate. We stress that the intensity of the UV light penetrating the cavity remains constant, which is ensured by the invariance of the spectrum around 330 nm. Hence, the change in rate cannot be attributed to a simple optical effect. The final concentrations of the species at the photostationary state are also modified, increasing the MC yield in the cavity by ca. 10%. Furthermore, it was checked that the when the cavity is designed in such a way to be out of resonance (at all angles) with the MC absorption transition, there is no change in rate (FIG. 3c) compared to the film outside the cavity.

A slowing of SPI-MC photoisomerization rate as the system enters strong coupling conditions is fully consistent with the change in energy landscape in FIG. 2e and Eq. (2). The upper lying |P+ [symbol] state will rapidly decay to |P− [symbol] which in turn by lying lower than the uncoupled excited state MC* will favour the return to ground state (path (1) over path (2) in FIG. 2e). The corresponding change in the rates k₁ and k₂ would result in a reduction in k_{obs} for the photoisomerization (through the decrease of the k₂/(k₁+k₂) term in Eq. (2)) and an increase in the photo-stationary concentration of coupled MC (k₁/k₂ increases in Eq. (3)) as observed.

While the modification of the reaction potential by strong coupling shown in FIGS. 1 and 2 emphasizes the splitting of the excited state energy levels, one must bear in mind that this modification will be felt through the entire system, reordering of the energy levels including possibly the ground state. If that is the case, the formation of the light-matter hybrid state might not only alter the photo-isomerization rates between SPI and MC, but also the thermal conversion of MC to SPI in the ground state energy landscape. Theoretical considerations of such ultra-strong coupling regime also predict a modification of the ground state energy (see references 11 and 12). Nevertheless, careful analysis of the thermal back reaction did not reveal any change in the rate beyond experimental error.

To gain further insight into the photochemical events, transient differential absorption spectroscopy (pump-probe) experiments were carried out on the coupled system and compared to that of the uncoupled molecules. This technique has the advantage of probing the excited states by detecting very small absorbance changes with minimal perturbation of the system, with the ability to also detect non-radiative decay processes in contrast to time-resolved fluorescence. FIG. 4a shows the transient spectra immediately after the 150 fs pump pulse (560 nm) for different coupling strengths. As can be seen the transient spectra are all very different from that of the uncoupled molecules. To understand these spectra, it is worth remembering that the transient differential absorption ΔA(λ) is given by Eq. (4) (see reference 33):

ΔA(λ)=[σ*(λ)−σ₀(λ)−σ_{SE}(λ)]κd[MC*] (4)

where σ*(λ) is the excited state absorption cross-section in cm⁻², σ₀(λ) the ground state absorption cross-section, σ_{SE}(λ) the stimulated emission cross-section of the excited state, κ the constant that relates the molar extinction coefficient to the cross-section (2.63×10²⁰ M⁻¹ cm) and d (cm) the pathlength or thickness of the film.

The spectra contain both positive peaks where the transient state absorbs more than the ground state and negative peaks at wavelengths where either the second and/or third term in Equation (4) dominate(s). The contribution of these terms to the spectra of the coupled system depends on the coupling strength in two ways. As the vacuum Rabi splitting increases, the photophysical properties of the coupled system are gradually modified but at the same time the fraction of coupled molecules increases. In other words, in such disordered molecular systems both coupled (polariton) and non-coupled (incoherent) states coexist (see references 6 and 7) and both are excited by the pump pulse and thereby contribute to the transient spectrum. At the strongest coupling strength, the transient absorption spectrum is dominated by the coupled system. This can be checked by changing the excitation to wavelengths where the coupled system absorbs more strongly as shown in FIG. 4b. By exciting at 670 nm directly in the ground state to |P− [symbol] absorption band, the transient spectrum is only slightly modified. This also indicates that the recorded transient spectrum for the coupled system is essentially the differential absorption between |P− [symbol] and ground state. In other words, the |P+ [symbol] state is too short lived to be detected in the 150 fs resolution of the apparatus. It is common in molecules that the lower excited state is the longest lived. That is why fluorescence is typically observed only from |P− [symbol] , if at all (see reference 21). Finally, it was also checked that the shape of the transient spectrum is invariant with the pump intensity and that the differential absorbance increases linearly (FIG. 4c), demonstrating thereby that the signal is due to a monophotonic transition to the excited state. It also confirms that the Rabi splitting is indeed defined by the coupling to the vacuum field.

The uncoupled (bare) molecules display a small amount of stimulated emission in the transient experiments and they also undergo spontaneous fluorescence from the lowest excited state, typical of aromatic organic molecules. The strongly coupled system showed no emission (spontaneous or stimulated) indicating again significant changes in the photophysical dynamics. The kinetics of the transient spectra are also modified by the strong coupling (inset FIG. 4b). The decay kinetics of the excited uncoupled MC is not a single exponential in agreement with other fs studies (see reference 30) and as discussed earlier it is due to the involvement of several intermediate isomers and matrix heterogeneity. The first half-life is ca. 30 ps while that of the coupled system is shortened to 10 ps (inset, FIG. 4b). This reduction in |P− [symbol] lifetime inside the cavity is totally consistent with the results of the steady-state irradiation experiments as discussed above.

The rearrangement of the molecular energy levels by coupling to the vacuum field has numerous important consequences for molecular and material sciences. As shown, it can be used to modify chemical energy landscapes and in turn the reaction rates and yields. Strong coupling can either speed up or slow down a reaction depending on the reorganisation of specific energy levels relative to the overall energy landscape. Both rates and the thermodynamics of the reaction will be modified. It is important not to confuse reaction modification by strong coupling in the vacuum field regime with such phenomena as photochemical reactions in strong fields where the molecules retain their electronic structure and the rates are enhanced by concentrating the light. Although the semi-classical approach can be used to predict the shape of the spectrum and the Rabi splitting in strongly coupled systems, it cannot account for the lifetime of the discrete states, their dynamics and their interrelationships. For this the quantum nature of the field needs to be invoked.

The coupling was done here to an electronic transition but it could also be done, as indicated earlier and illustrated later, to a specific vibrational transition for instance to modify the reactivity of a bond. In this way, it can be seen as analogous to a catalyst which changes the reaction rate by modifying the energy landscape. Like all chemical reactions, the effect is favoured by higher concentrations but for a different reason—here it modifies the energy landscape and not just simply the collision rates. Since the formation of hybrid states changes the energy levels at play, it will in principle modify the ionisation potential and the electron affinity of the system. So not only the redox reactions are affected, but also the work function of the coupled material is modified. Fine tuning the work function by strong coupling to vacuum fluctuations implies significant consequences for device design and performance, for instance in the case of organic light emitting diodes, photovoltaics and molecular electronics. It is important to note that in the context of the concerned applications, strong coupling is not limited to the Fabry-Perot configuration used here. Any photonic structure that provides a sufficiently sharp resonance can be used. When using molecular materials with large transition dipole moments, even low-quality resonators are sufficient to generate strong coupling, especially when the mode-volume is small such as in the case of a metallic microcavity or a confined surface plasmon resonance generated on metallic hole arrays (see references 19 to 27). Such “open” plasmonic structures can be accessed more easily for further characterisation and for connection to more complex functionalities.

The harvesting of cavity vacuum fields for modifying chemical reaction landscapes and material properties puts an entirely new tool into the hands of the chemist for influencing useful reactions, with important implications for material science and molecular devices.

A second example carried out by the inventors of possible applications of the invention concerns the possibility of tuning the work function via strong coupling, as described hereinafter.

As known by the man skilled in the art, all materials are characterized by a work function, the energy necessary to remove an electron from the solid into vacuum, a fundamental property which is critical for many applications. Electronic devices for instance, such as organic transistors and solar cells, will be designed with sets of metal electrodes carefully chosen according to their intrinsic work function (see references 34 to 38). The work function can be further adjusted by chemical modification of the interface to optimize the performance of such devices (see references 39 and 40).

The invention proposes a new way of tuning the work function by providing the conditions for realizing a resonant interaction with the local electromagnetic environment, by strongly coupling a molecular material with the vacuum electromagnetic field.

A first feature of strong coupling for material and molecular science is its collective nature. In a molecular material, the Rabi-splitting of each molecule is determined by the square root of the molecular concentration within the optical mode and values up to 700 meV have been reported (see reference 41) which have been shown to modify chemical reactivity (see previously described example). Molecules microns apart will emit coherently if they are strongly coupled to the same mode (see reference 42).

An other feature resulting from equation (1), and as already indicated, is that even in the dark, the interaction of the material with the vacuum field via the photonic structure can be very strong, leading to a major reorganization of the energy levels of the system.

As a consequence, the material properties of the ensemble also change. For instance, the electron affinity, Eₐ, and to a lesser degree the ionisation potential Iₚ, will be modified together with the work function Φ as illustrated in FIG. 1b. Note that here Φ is assumed to be halfway between the highest occupied state and the lowest unoccupied one, as a first approximation for highly doped polymers.

In order to illustrate practical applications of these features and verify the principles of the invention, a polymer film doped with the photochrome spiropyran (SPI) was coupled to two different resonant structures 1, a metallic hole array and a Fabry-Perot cavity as illustrated in FIGS. 5a and 5b.

The inventors have established that the first transition (560 nm) of the coloured form of the photochrome (FIG. 2a), merocyanine (MC), can be strongly coupled with these structures leading to exceptionally large vacuum Rabi splittings (see reference 41). Furthermore, the degree of coupling can be adjusted by UV irradiation of the uncoloured form to control [MC] and thereby [symbol] Ω_{R} since it is proportional to \sqrt{[MC]}. Kelvin Probe Force Microscopy (KPFM) (see references 43 and 44) was used to extract the work function of the samples, a technique which simultaneously maps the surface morphology and electric surface potential as schematically illustrated in FIG. 6.

A series of hole arrays with different periods were milled using focused ion beam (FIB) in a 200 nm thick Ag film. A PMMA film (150 nm thick) containing the SPI (density ˜10%) was then spin-coated on the surface. An AFM image of such a sample is shown in FIG. 7a together with the corresponding KPFM image (FIG. 7b). The transmission spectra of the arrays were recorded by optical microscopy which showed the typical extraordinary transmission peaks associated with the surface plasmon modes (see references 45 and 25) (black curve, FIG. 8a). The sample was then irradiated at 365 nm to generate MC. When the (1,0) surface plasmon mode was resonant with the 560 nm MC peak (period P=250 nm), a splitting occurs which here reaches a maximum of 600 meV, a typical signature of strong coupling (red curve, FIG. 8a). As the period increases and the surface plasmon mode is detuned from the MC transition, the strong coupling vanishes (reference 41).

The work function was then measured for the same set of periods before and after UV irradiation, the samples before irradiation with the SPI isomer acting as a reference.

As shown in FIG. 8b, the observed change in work function ΔΦ_{obs} between the two isomers is maximum when the surface plasmon mode is resonant with the MC transition (P=250 nm), i.e. when the system is most strongly coupled. Nevertheless, ΔΦ_{obs} (125 meV at P=250 nm) is an underestimation of the true shift in the work function ΔΦ=Φᵢ−Φ_{sc}. This is because the surface plasmon modes of the array have angular dispersion (see references 45 and 25) and the probe averages over a large solid angle, thereby blurring the true value of ΔΦ. For the hole array sample a very small probe (radius several nm) was used to have the needed spatial resolution. A simple calculation taking into account the geometry of this particular KPFM tip and the angular response function of the dispersion confirms this averaging process on ΔΦ_{obs} (FIG. 8c).

In order to approach the absolute value of ΔΦ, a different geometry was chosen. First, Fabry-Perot (FP) structures resonant with MC were prepared as these cavities have much smaller angular dispersion. Secondly theses FP were made over a large area which allowed to do KPFM measurements using a much bigger probe (2 mm diameter) thereby reducing significantly the contributions from angles other than those normal to the FP surface. The FP cavities were prepared so that the lowest MC absorption transition (560 nm) was strongly coupled to the X, mode of the FP, as shown spectroscopically in FIG. 9a. The corresponding Rabi splitting is 650 meV. Upon UV irradiation, ΔΦ_{obs} evolves with time as expected from the kinetics of the photoisomerization of the photochrome (FIG. 9b). The maximum observed change in the work function is much larger in this sample geometry, reaching a value of 175 meV. As a control, a sample of the same thickness but with only the PMMA polymer showed no change upon irradiation (green curve, FIG. 9b). A more important control is the off-resonance sample which consists of the SPI doped PMMA layer of a thickness such as that the cavity resonance is detuned from the MC absorption and thus cannot result in strong coupling. Upon irradiation, this off-resonance sample showed a slight decrease of Φ (a few tens meV) with the formation of MC. The total observed shift in Φ between the on and off-resonance is therefore ca. 200 meV.

Considering the effect of the Rabi splitting on the redistribution of the energy levels (FIG. 1b), one expects in a first approximation an absolute change in work function ΔΦ=Φᵢ−Φ_{sc}˜¼ [symbol] Ω_{R} if the ground state energy level does not shift. A ΔΦ_{obs} of 200 meV appears therefore close to the maximum for a splitting of [symbol] Ω_{R}=650 meV. Given that here, the system is in the so-called ultra-strong coupling regime ( [symbol] Ω_{R} is 30% of the MC transition energy), it is possible that the ground state energy of the coupled system is also modified. This would further change Φ beyond ¼ [symbol] Ω_{R} estimated from the simplest considerations.

As already known (see references 39 and 40), the change in work function induced by strong coupling is smaller than that achievable by chemical modification. Nevertheless, it has the advantage that it can be easily fine-tuned to a desired value which is naturally critical for many applications. This is especially true for organic devices such as transistors, light emitting devices and solar cells. It can also be dynamically controlled when using functional molecules such as photochromes and electro chromes.

The strong coupling is angle dependent when involving a dispersive photonic resonance. As a consequence, it is possible to construct devices where the work function is also angle dependent which can be useful for certain applications. For instance, thermionic emission could be engineered to occur at a given angle.

Tunability of the work function through strong coupling should be quite easy to implement in practice. For instance, the distance between two metallic electrodes or dielectric mirrors in a sandwich structure could be adjusted to resonate with an electronic transition in the material.

Alternatively, plasmonic resonance could be used either with non-dispersive localized modes or delocalized ones as illustrated before. Strong coupling could also be used to simultaneously tailor other properties of the material, electronic or opto-electronic, through the change in the energy levels.

Finally, this non-optical observation of strong coupling described before confirms that strongly coupled materials are fundamentally modified even in the absence of light by the formation of new hybrid states.

A third example of a possible application of the principle of the invention is described hereinafter in relation to the field of NMR and in connection with FIGS. 10 and 11.

It is common knowledge, in the field of nuclear magnetic resonance (NMR), that a magnetic field (B≠0) lifts the degeneracy between two spin states, for instance α and β of a nucleus as illustrated in FIG. 10. Then an electromagnetic wave with frequency ω_{NMR} probes the transition between α and β: the (magnetic) resonance.

The higher the NMR frequency, the better the signal to noise ratio and the higher the spectral resolution of the equipment.

The NMR frequency is directly proportional to the applied magnetic field B. The problem is that increasing the magnetic field increases the cost much faster. High frequency NMR machines are therefore very expensive.

In accordance with the invention, a solution to this problem is proposed by increasing the resonant frequency without increasing the magnetic field. Indeed, by using the principle of strong coupling to the NMR, transition can be split by the Rabi frequency [symbol] Ω_{R} which modifies the largest transition frequency by half the Rabi splitting to give ω_{SC} as shown in FIG. 10.

As a practical illustrative example, a Cobalt sample was placed in a tunable resonant cavity. The Co provides its own internal magnetic field and as a consequence has an NMR transition at ca. 213 MHz. Two kinds of measurements—transmission and reflection—were made, with the spectral response measured while the cavity resonance is swept across the NMR resonance of the Cobalt sample. Due to the high impedance mismatch most of the signal is reflected from the cavity. The initial Q-factor of the (empty) resonator was measured to be around 1000, but because of losses in the cobalt it drops down to about 50 when the sample is placed inside the resonator (reflective structure).

As can be seen in FIG. 11, there is a small splitting in the peak and a sudden jump in the transmission peak for positive detuning, which is accompanied by a slight broadening of the resonance. This is apparently due to the strong coupling of the spin transition (NMR transition) of cobalt to the cavity resonance.

The person skilled in the art will easily understand that it is expected that if the strong coupling with the NMR transition is further improved and optimized, the system will enter into the ultra-strong coupling regime where the Rabi splitting is 30 to 40% of the transition. In such case the NMR frequency will go up by 15 to 20%. For instance if the apparatus originally operates at 700 MHz, then with strong coupling it will move to 800 to 850 MHz. In addition, this inventive feature is fairly easy to implement since it will only require the introduction of a cavity structure in the NMR apparatus.

The following publications are mentioned hereinbefore as references (quoted with their respective reference number indicated below), their contents being incorporated herein by reference in connection with the concerned subject matter of the specification:
1. D. Snoke, P. Littlewood, Physics Today 2010, 63, 42-47.
2. J. M. Raimond, M. Brune, S. Haroche, Rev. Mod. Phys. 2001, 73, 565-582.
3. M. S. Skolnick, T. A. Fisher, D. M. Whittaker, Semicond. Sci. Technol. 1998, 13, 645-669.
4. C. Weisbuch, M. Nishioka, A. Ishikawa, Y. Arakawa, Phys. Rev. Lett. 1992, 69, 3314-3317.
5. V. Savona, L. C. Andreani, P. Schwendimann, A. Quattropani, Solid State Comm. 1995, 93, 733-739.
6. V. M. Agranovitch, M. Litinskaia, D. G. Lidzey, Phys. Rev. B 2003, 67, 085311.
7. M. Litinskaya, P. Reineker, V. M. Agranovich, J. Luminescence 2004, 110, 364-372.
8. J. P. Reithmaier, G. S [symbol] k, A. Löffler, C. Hofmann, S. Kuhn, S. Reitzenstein, L. V. Keldysh, V. D. Kulakovskii, T. L. Reinecke, A. Forchel, Nature 2004, 432, 197-200.
9. T. Yoshie, A. Scherer, J. Hendrickson, G. Khitrova, H. M. Gibbs, G. Rupper, C. Ell, 0. B. Shchekin, D. G. Deppe, Nature 2004, 432, 200-203.
10. G. Zumofen, N. M. Mojarad, V. Sandoghdar, M. Agio, Phys. Rev. Lett. 2008, 101, 180404.
11. C. Ciuti, G. Bastard, I. Carusotto, Phys. Rev. B 2005, 72, 115303.
12. A. A. Anappara, S. De Liberato, A. Tredicucci, C. Ciuti, G. Biasiol, L. Sorba, F. Beltram, Phys. Rev. B 2009, 79, 201303(R).
13. S. Haroche, D. Kleppner, Physics Today 1989, 42, 24-30.
14. R. J. Thompson, G. Rempe, H. J. Kimble, Phys. Rev. Lett. 1992, 68, 1132-1135.
15. Kasprzak, J. et al. Bose-Einstyein condensation of exciton polaritons. Nature 443, 409-414 (2006).
16. Kelkar, P. V. et al. Stimulated emission, gain, and coherent oscillations in II-VI semiconductors cavities. Phys. Rev. B 56, 7564-7573 (1997).
17. Saba, M. et al. High-temperature ultrafast polariton parametric amplification in semiconductor cavities. Nature 414, 731-735 (2001).
18. Stievater, T. H. et al. Rabi oscillations of excitons in single quantum dots. Phys. Rev. Lett. 87, 133603 (2001).
19. D. G. Lidzey, D. D. C. Bradley, M. S. Skolnick, T. Virgili, S. Walker, D. M. Whittaker, Nature 1998, 395, 53-55.
20. P. A. Hobson, W. L. Barnes, D. G. Lidzey, G. A. Gehring, D. M. Whittaker, M. S. Skolnick, Appl. Phys. Lett. 2002, 81, 3519-3521.
21. J. Bellessa, C. Bonnand, J. C. Plenet, J. Mugnier, Phys. Rev. Lett. 2004, 93, 036404.
22. R. J. Holmes, S. R. Forrest, Phys. Rev. Lett. 2004, 93, 186404.
23. F. Sasaki, S. Haraichi, S. Kobayashi, Quant. Elec. 2002, 38, 943-948.
24. J. R. Tischler, M. S. Bradley, V. Bulovié, Phys. Rev. Lett. 2005, 95, 036401.
25. J. Dintinger, S. Klein, F. Bustos, W. L. Barnes, T. W. Ebbesen. Phys. Rev. B 2005, 71, 035424.
26. A. Salomon, C. Genet, T. W. Ebbesen, Angew. Chem. Int. Ed. 2009, 48, 8748-8751.
27. T. K. Hakala, J. J. Toppari, A. Kuzyk, M. Pettersson, H. Tikkanen, H. Kunttu, P. Törmä, Phys. Rev. Lett. 2009, 103, 053602.
28. C. Lenoble, R. S. Becker, J. Phys. Chem. 1986, 90, 62-65.
29. A. K. Chibisov, H. Görner, J. Phys. Chem. A 1997, 101, 4305-4312.
30. J. Hobley, U. Pfeifer-Fukumura, M. Bletz, T. Asahi, H. Masuhara, H. Fukumura, J. Phys. Chem. A 2002, 106, 2265-2270.
31. C. J. Wohl, D. Kuciauskas, J. Phys. Chem. B 2005, 109, 22186-22191.
32. G. Such, R. A. Evans, L. H. Yee, T. P. Davis, Polym. Rev. 2003, 43, 547-579.
33. M. Becker, V. Nagarajan, W. W. Parson, J. Am. Chem. Soc. 1991, 113, 6840-6848.
34. Yuan, Y. et al. Efficiency enhancement in organic solar cells with ferroelectric polymers. Nature Mater. 10, 296-302 (2011).
35. Meijer, E. J. et al. Solution-processed ambipolar organic field-effect transistors and inverters. Nature Mater. 2, 678-682 (2003).
36. Vandewal, K. Tvingstedt, K. Gadisa, A., Inganäs, O. & Manca, J. V. On the origin of the open-circuit voltage of polymer-fullerene solar cells. Nature Mater. 8, 904-909 (2009).
37. Liang, Y. et al. For the bright future-bulk heterojunction polymer solar cells with power conversion efficiency of 7.4%. Adv. Mater. 22, 1-4 (2010).
38. van Woudenbergh, Blom, P. W. M. Blom & Huiberts, J. N. Appl. Phys. Lett. 82, 985-(2003).
39. de Boer, B. Hadipour, A. Mandoc M. M., van Woudenbergh, T. & Blom, P. W. M. Tuning of metal work functions with self-assembled monolayers. Adv. Mat. 17, 621-625 (2005).
40. Petr, A., Zhang, F., Peisert, H., Knupfer, M. & Dunsch, L. Electrochemical adjustment of the work function of a conducting polymer. Chem. Phys. Lett. 385, 140-143 (2004).
41. Schwartz, T., Hutchison, J. A., Genet, C. & Ebbesen, T. W. Reversible switching of ultrastrong light-molecule coupling. Phys. Rev. Lett. 106, 196405 (2011)
42. Abeera Guebrou, S. et al. Coherent emission from a disordered organic semiconductor induced by strong coupling with surface plasmons. Phys. Rev. Lett. 108, 0666401 (2012).
43. Liscio, A., Palermo, V. & Samori, P. Nanoscale quantitative measurement of the potential of charged nanostructures by electrostatic and Kelvin probe force microscopy: unraveling electronic processes in complex materials. Acc. Chem Res. 43, 541-550 (2010).
44. Liscio, A., Palermo, V., Mullen, K. & Samori, P. Tip-sample interactions in Kelvin probe force microscopy: quantitative measurement of the local surface potential. J. Phys. Chem. 112, 17368-17377 (2008).
45. Ebbesen, T. W., Lezec, H. J., Ghaemi, H. F., Thio, T. & Wolff, P. A. Extraordinary optical transmission through sub-wavelength hole arrays. Nature 391, 667-69 (1998).

Of course, the invention is not limited to the preferred embodiments described and represented herein, changes can be made or equivalents used without departing from the scope of the invention.

1-27. (canceled)

28. A method to modify the chemical properties, the work function, the electrochemical potential and/or the nuclear magnetic resonance frequency of one or more molecules, biomolecules or materials, said method comprising the steps of:
providing a reflective or photonic structure (1) which has an electromagnetic mode which is resonant with a transition in said molecules, biomolecules or material (2);
placing said molecule(s), biomolecule(s) or material (2) in or on a structure of the previous type,
the method further comprising, by means of strong coupling to local electromagnetic vacuum field and exploiting the resulting rearrangement of the energy levels of the molecules, biomolecules or materials, controlling a chemical reaction by influencing at least one of the following criteria or parameters of said reaction: reactivity of the molecules, biomolecules or material intended to react; kinetics of the reaction; rate and/or yield of the reaction; thermodynamics of the reaction.

29. A method to modify the chemical properties, the work function, the electrochemical potential and/or the nuclear magnetic resonance frequency of one or more molecules, biomolecules or materials, said method comprising the steps of:
providing a reflective or photonic structure (1) which has an electromagnetic mode which is resonant with a transition in said molecules, biomolecules or material (2);
placing said molecule(s), biomolecule(s) or material (2) in or on a structure of the previous type,
the method further comprising, by means of strong coupling to local electromagnetic vacuum field and exploiting the resulting rearrangement of the energy levels of the molecules, biomolecules or materials, tuning or dynamically controlling the value of the work function of the molecules, biomolecules or material.

30. The method according to claim 28, wherein a Q-factor defined as the ratio of the wavelength of the resonance divided by the half-width of the resonance of the electromagnetic mode is at least 10.

31. The method according to claim 28, wherein the electromagnetic mode is a surface plasmon mode.

32. The method according to claim 28, wherein the electromagnetic mode is a cavity mode.

33. The method according to claim 28, wherein the reflective structure is made of a metal film (3) or of two opposed metal films (3, 3′).

34. The method according to claim 28, wherein the concerned transition in the molecules, biomolecules or material is an electronic transition.

35. The method according to claim 28, wherein the concerned transition in the molecules, biomolecules or material is a vibrational transition.

36. The method according to claim 28, wherein the concerned transition in the molecules, biomolecules or material is a nuclear spin transition.

37. The method according to claim 28, further comprising providing a dispersive photonic resonance mode and using the angle dependency of the work function to control, to monitor or to influence a transition in said molecules, biomolecules or material and/or to selectively exploit or to model the results of said transition.

38. The method according to claim 29, wherein the method is applied to a functional device comprising said reflective or photonic structure, said device being one of an electronic device, an optical device or a photovoltaic device.

39. The method according to claim 29, further comprising using the reflective or photonic structure (1) in order to modify the electron affinity and the ionisation potential of the molecules, biomolecules and material placed in or on it.

40. A machine or apparatus able and intended to perform at least one electronic, optic, magnetic or chemical function, wherein said machine or apparatus comprises at least one device comprising a reflective or photonic structure (1) which has an electromagnetic mode which is resonant with a transition in said molecules, biomolecules or material (2), said structure (1) being confined or open and being designed to perform the method according to claim 28.

41. The machine or apparatus according to claim 40, wherein the Q-factor of the electromagnetic mode of the reflective or photonic structure (1) is at least 10.

42. The machine or apparatus according to claim 40 wherein the concerned transition in the molecules, biomolecules or material is an electronic transition.

43. The machine or apparatus according to claim 40 wherein the concerned transition in the molecules, biomolecules or material is a vibrational transition.

44. The machine or apparatus according to claim 40 wherein the reflective or photonic structure (1) comprises plasmonic structures, the electromagnetic mode being a surface plasmon mode.

45. The machine or apparatus according to claim 40 wherein the reflective or photonic structure (1) consists of an optical microcavity, preferably a Fabry-Perot cavity, the electromagnetic mode being a cavity mode.

46. The machine or apparatus according to claim 40 wherein the reflective structure (1) is made of a metal film (3) or of two opposed metal films (3, 3′).

47. The machine or apparatus according to claim 40, wherein said device is an electronic device.

48. The machine or apparatus according to claim 40, wherein said device is an optical device.

49. The machine or apparatus according to claim 40, wherein said device is a photovoltaic device.

50. The machine or apparatus according to claim 40, wherein said machine is a NMR spectroscopy or imaging machine and said device is a sample holder or part of a sample holder of said NMR machine, the reflective structure of said device having an electromagnetic mode which is resonant with the nuclear spin transition(s) to be analyzed or detected.

51. The machine or apparatus according to claim 40, wherein the reflective structure (1) comprises two metallic electrodes or two dielectric mirrors in a sandwich structure, the distance between said electrodes or mirrors being adjusted to resonate with an electronic transition in the molecules, biomolecules or material arranged within said structure.
